(19) United States
(12) Patent Application Publication
(10) Pub. No.: US 2026/0068208 A1
(43) Pub. Date: Mar. 5, 2026

(54) SEMICONDUCTOR DEVICE AND MANUFACTURING METHOD THEREOF

(71) Applicant: Fujitsu Limited, Kawasaki-shi (JP)

(72) Inventors: Jun TANIGUCHI, Isehara (JP); Atsushi YAMADA, Hiratsuka (JP)

(73) Assignee: Fujitsu Limited, Kawasaki-shi (JP)

(21) Appl. No.: 19/283,022

(22) Filed: Jul. 28, 2025

(30) Foreign Application Priority Data
Aug. 28, 2024 (JP) 2024-146647

(51) Int. Cl. H10D 30/47; H10D 30/01; H10D 62/10; H10D 62/824; H10D 64/27; H10D 64/68

(52) U.S. Cl. CPC H10D 30/475; H10D 62/102; H10D 62/824; H10D 64/516; H10D 64/518; H10D 64/685; H10D 64/691; H10D 64/693; H10D 30/015

(57) ABSTRACT

A semiconductor device has a channel layer that is a nitride semiconductor, and a barrier layer that is a layer of another nitride semiconductor with a wider bandgap, in this order. The semiconductor device further has a first protective layer that is a layer of a first insulator, and a second protective layer that is a layer of a second insulator thicker than the first protective layer, on or above the barrier layer. The semiconductor device further has a drain electrode, a source electrode and a gate electrode. The first insulator is more difficult to remove by certain dry etching than the second insulator. At least a portion of the gate electrode is arranged in a through portion that penetrates through the second protective layer. A portion of the first protective layer is arranged under the through portion, or the first protective layer arranged in the through portion.

### CROSS-REFERENCE TO RELATED APPLICATION

This application is based upon and claims the benefit of priority of the prior Japanese Patent Application No. 2024-146647, filed on Aug. 28, 2024, the entire contents of which are incorporated herein by reference.

### FIELD

The embodiments discussed herein are related to a semiconductor device and a manufacturing method thereof.

### BACKGROUND

A field effect transistor that has a layer of a nitride semiconductor, and a layer of another nitride semiconductor with a wider bandgap than that of the nitride semiconductor in this order (which will be hereinafter referred to as a nitride transistor) is a new-generation power transistor (e.g., see Japanese Laid-open Patent Application Publication No. 2014-170934 and U.S. Patent Application Publication No. 2012/0156836).

A nitride transistor typically has a passivation film arranged on a barrier layer (i.e., the “another nitride semiconductor with a wider bandgap”) (see e.g., Japanese Laid-open Patent Application Publication No. 2014-170934, U.S. Patent Application Publication No. 2012/0156836, Japanese National Publication of International Patent Application No. 2016-539496, and U.S. Patent Application Publication No. 2013/0153963). The passivation film on the barrier layer is typically arranged for suppressing current collapse (see e.g., Japanese Laid-open Patent Application Publication No. 2014-170934, U.S. Patent Application Publication No. 2012/0156836, and Japanese National Publication of International Patent Application No. 2016-539496).

### SUMMARY

According to an aspect of the embodiments, an apparatus includes a channel layer that is a first nitride semiconductor; a barrier layer that is a layer of a second nitride semiconductor with a wider bandgap than that of the first nitride semiconductor, and is arranged on or above the channel layer; a first protective layer that is a layer of a first insulator, and is arranged on or above the barrier layer; a second protective layer that is a layer of a second insulator, is thicker than the first protective layer, and is arranged on or above the barrier layer; a drain electrode into which a current that flows through the channel layer flows; a source electrode that extends along the drain electrode, and from which the current flows out; and a gate electrode that is arranged between the source electrode and the drain electrode, and is isolated from the barrier layer, wherein the first insulator is an insulator that is more difficult to remove by a certain dry etching than the second insulator, at least a portion of the gate electrode is arranged in a through portion that penetrates through the second protective layer, and a portion of the first protective layer is arranged under the through portion, or the first protective layer is arranged in the through portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a plan view illustrating one example 2 of a semiconductor device in accordance with Embodiment 1;

FIG. 2 is a cross sectional view of an important part for the operation of a nitride transistor 2 among the cross sections along line II-II depicted in FIG. 1;

FIG. 3 is a cross sectional view of the first protective layer 14a and the second protective layer 14b in the vicinity of the gate electrode 20;

FIG. 4 is a view comparing the etching rates of SiAlN and SiN;

FIG. 5 is a view for illustrating one example of the operation of the nitride transistor 2;

FIG. 6 is a cross sectional view of a nitride transistor 202 that has a SiN layer 214 in place of the first protective layer 14a and the second protective layer 14b;

FIG. 7 is a cross sectional view of a nitride transistor 302 that has a SiN layer 314 with a dent 315 in place of the first protective layer 14a and the second protective layer 14b;

FIG. 8 is a cross sectional view of a nitride transistor 402 that has a thin SiAlN layer 414 in place of the first protective layer 14a and the second protective layer 14b;

FIG. 9 is a cross sectional view of a nitride transistor 502 that has a sufficiently thick SiN layer 514 in place of the first protective layer 14a and the second protective layer 14b;

FIG. 10A is a process cross-sectional view depicting one example of a method for manufacturing the nitride transistor 2;

FIG. 10B is a process cross-sectional view depicting one example of a method for manufacturing the nitride transistor 2;

FIG. 11A is a process cross-sectional view depicting one example of a method for manufacturing the nitride transistor 2;

FIG. 11B is a process cross-sectional view depicting one example of a method for manufacturing the nitride transistor 2;

FIG. 12A is a process cross-sectional view depicting one example of a method for manufacturing the nitride transistor 2;

FIG. 12B is a process cross-sectional view depicting one example of a method for manufacturing the nitride transistor 2;

FIG. 13 is a cross sectional view of one example 602 of a semiconductor device in accordance with Embodiment 2;

FIG. 14 is a cross sectional view of the first protective layer 614a and the second protective layer 614b in the vicinity of the gate electrode 620;

FIG. 15A is a process cross-sectional view illustrating one example of the method for manufacturing the nitride transistor 602;

FIG. 15B is a process cross-sectional view illustrating one example of the method for manufacturing the nitride transistor 602;

FIG. 16A is a process cross-sectional view illustrating one example of the method for manufacturing the nitride transistor 602;

FIG. 16B is a process cross-sectional view illustrating one example of the method for manufacturing the nitride transistor 602;

FIG. 17A is a process cross-sectional view illustrating one example of the method for manufacturing the nitride transistor 602;

FIG. 17B is a process cross-sectional view illustrating one example of the method for manufacturing the nitride transistor 602;

FIG. 18A is a process cross-sectional view illustrating one example of the method for manufacturing the nitride transistor 602; and

FIG. 18B is a process cross-sectional view illustrating one example of the method for manufacturing the nitride transistor 602.

### DESCRIPTION OF EMBODIMENTS

AS described previously, a nitride transistor has a channel layer (i.e., “a nitride semiconductor”) and a barrier layer (i.e., the “another nitride semiconductor with a wider bandgap”).

A barrier layer (e.g., an AlGaN layer) of a nitride transistor is configured such that positive polarization electric charges are generated on the hetero interface between the barrier layer and the channel layer (e.g., a GaN layer). The positive polarization charges generate a two dimensional electron gas in the channel layer of the nitride transistor.

Incidentally, the description “AlGaN layer” in parentheses refers to the layer of AlGaN (i.e., “the layer made of AlGaN” or “the layer that is AlGaN”). The same also applies to the “GaN layer” and the same description described latter (i.e., “layer of-”).

The density of the two dimensional electron gas generated in the channel layer varies according to the potential difference between the gate electrode and the source electrode (i.e., the gate voltage), which are arranged on or above the barrier layer. When the gate electrode is applied with an alternating voltage, the density of the two dimensional electron gas also varies according to the change in alternating voltage. As a result, a large alternating current flows to the nitride transistor. Namely, the nitride transistor is a transistor that has a large mutual conductance.

Incidentally, the passivation film on the barrier layer typically has a through portion (i.e., a cavity that penetrates through the passivation film), and a gate electrode is arranged at the through portion. The through portion of the passivation film is typically formed by dry etching with large anisotropy. When etching proceeds, and the through portion is completed, the upper surface of the barrier layer revealed at the bottom of the through portion is exposed to a plasma generated during dry etching.

The present inventors found out that exposure of the barrier layer to the plasma results in the reductions of the density and the mobility of the two dimensional electron gas (precisely, the mobility of the electrons in the two dimensional electron gas). The reductions thereof make it difficult to achieve higher output power and high frequency response of nitride transistors.

The problem is particularly remarkable for a nitride transistor that has an InAlGaN barrier layer and is therefore suitable for higher output.

### Embodiments of the Present Invention Will Be Described

hereinafter according to drawings. However, it is noted that the technical scope is not limited to the embodiments described below, but covers the matters described in the claims and the equivalents thereof. Here, identical symbols are given to identical parts even in different drawings, and the description thereof will be omitted.

### Embodiment 1

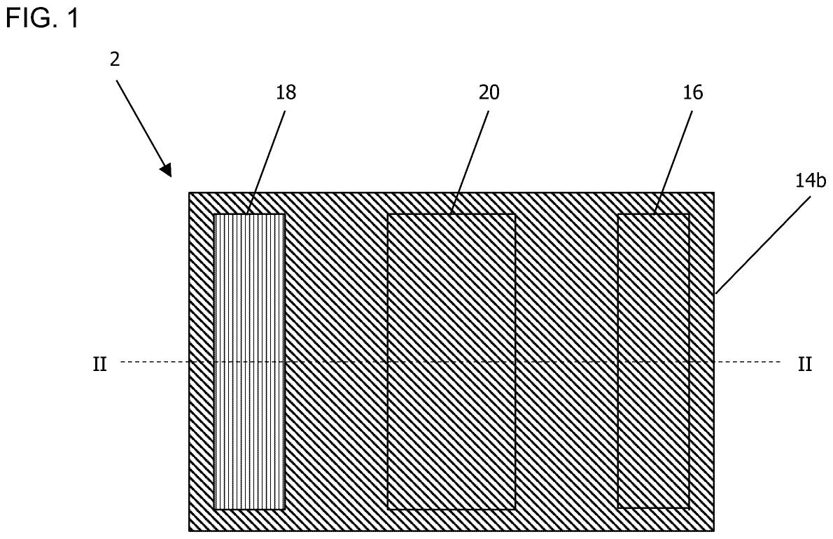

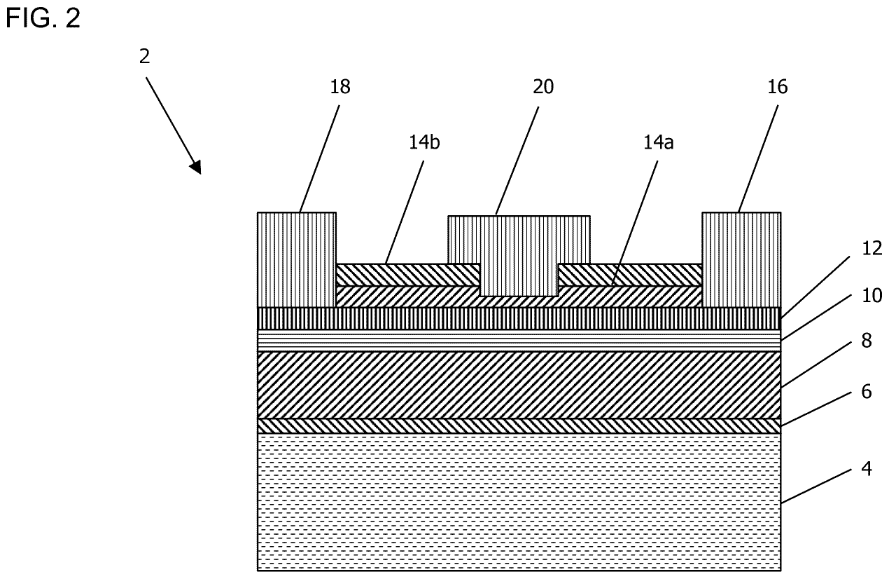

FIG. 1 is a plan view illustrating one example 2 of a semiconductor device in accordance with Embodiment 1 (which will be hereinafter referred to as a nitride transistor). FIG. 2 is a cross sectional view of an important part for the operation of a nitride transistor 2 among the cross section along line II-II depicted in FIG. 1. The same also applies to other cross sectional views described later.

### (1) Structure

The nitride transistor 2 has a substrate 4, an AlN nucleation layer 6, a channel layer 8, a spacer layer 10, a barrier layer 12, a first protective layer 14a that is an insulator, and a second protective layer 14b that is another insulator in this order. The nitride transistor 2 further has a drain electrode 16, a source electrode 18, and a gate electrode 20.

### (1-1) Substrate 4 and AlN Nucleation Layer 6

The nitride transistor 2 has a substrate 4 (e.g., a semi-insulating SiC substrate), and an AlN nucleation layer 6 as illustrated in FIG. 2. The AlN nucleation layer 6 is also referred to as an AlN low temperature buffer layer.

The AlN nucleation layer 6 is a buffer layer that enables growth of a high quality nitride semiconductor on a substrate (e.g., a SiC substrate) largely different in lattice constant from nitride semiconductors. The AlN nucleation layer 6 is a polycrystalline film or an amorphous film of AlN formed at low temperatures. When a substrate that has a lattice constant equal to, or substantially equal to that of the channel layer 8 (e.g., a GaN channel layer) is used, the AlN nucleation layer 6 may be omitted. Such a substrate is, for example, a GaN substrate.

### (1-2) Channel Layer 8 and Barrier Layer 12

The nitride transistor 2 further has a layer 8 (which is referred to as a channel layer where appropriate) of a nitride semiconductor (which is referred to as a first nitride semiconductor where appropriate), on the AlN nucleation layer 6. The first nitride semiconductor (e.g., GaN) is a group III-V semiconductor, and one of the constituent elements thereof is preferably Ga.

The nitride transistor 2 further has a barrier layer 12 that is a layer of a nitride semiconductor (which is referred to as a second nitride semiconductor where appropriate) with a wider bandgap than that of the first nitride semiconductor, and is arranged above the channel layer 8.

The second nitride semiconductor (e.g., InAlGaN or AlGaN) is also a group III-V semiconductor, and at least two of the constituent elements thereof are preferably two elements selected from the group that consists of In, Al, and Ga. The second nitride semiconductor may be AlN.

### (1-3) Spacer Layer 10

The nitride transistor 2 further has a spacer layer 10 that is a layer of a nitride semiconductor, and is arranged between the channel layer 8 and the barrier layer 12.

The spacer layer 10 is a layer (e.g., an AlGaN layer) configured to relax the intensity of the electric field generated at the barrier layer 12 by the potential difference between the gate electrode 20 and the drain electrode 16. Therefore, the spacer layer 10 may suppress the breakage of the barrier layer 12 caused by the electric field concentration in the vicinity of the gate electrode 20 (particularly, the vicinity of the gate electrode end on the drain electrode 16 side).

For a nitride transistor in which the barrier layer 12 tends to be broken by electric field concentration (e.g., a nitride transistor that has an InAlGaN barrier layer), the spacer layer 10 is useful. On the other hand, for a nitride transistor in which the barrier layer 12 is less likely to be broken by electric field concentration (e.g., a nitride transistor that has an AlGaN barrier layer), the spacer layer 10 may be omitted.

### (1-4) First Protective Layer 14a

The nitride transistor 2 further has a first protective layer 14a that is a layer of an insulator (which is referred to as a first insulator where appropriate), and is arranged on the barrier layer 12.

The first protective layer 14a is, for example, a layer of SiAlN. SiAlN is a compound resulting from bonding of 3 elements of silicon (Si), aluminum (Al), and nitrogen (N). An insulator is reduced in resistance upon crystallization. For this reason, the first protective layer 14a is preferably amorphous.

### (1-5) Second Protective Layer 14b

The nitride transistor 2 further has a second protective layer 14b that is a layer of an insulator (which is referred to as a second insulator where appropriate), is thicker than the first protective layer 14a, and is arranged above the barrier layer 12 with the first protective layer 14a in between (precisely, with the first protective layer 14a being sandwiched between the barrier layer 12 and the second protective layer 14b). As described above, an insulator is reduced in resistance upon crystallization. For this reason, the second protective layer 14b is also preferably amorphous as with the first protective layer 14a.

The second protective layer 14b is, for example, a layer of SiN. SiN is a compound resulting from bonding of two elements of silicon (Si) and nitrogen (N).

### (1-6) Drain Electrode 16 and Source Electrode 18

The nitride transistor 2 further has a drain electrode 16 into which a current that flows through the channel layer 8 flows, and a source electrode 18 that extends along the drain electrode 16 and from which the current flows out (see “(3) Operation”).

In each example depicted in FIGS. 1-2, the source electrode 18 and the drain electrode 16 are ohmic electrodes in contact with the barrier layer 12. However, the source electrode 18 and the drain electrode 16 are not limited to such electrodes.

For example, the nitride transistor 2 may have low resistance GaN that penetrates through the barrier layer 12 and the spacer layer 10, and reaches the channel layer 8. The source electrode 18 may be an ohmic electrode in contact with such a low resistance GaN. The same also applies to the drain electrode 16.

### (1-7) Gate Electrode 20

The nitride transistor 2 further has a gate electrode 20 that is an electrode arranged between the source electrode 18 and the drain electrode 16 in a plan view, and is isolated from the barrier layer 12.

### (1-8) Gate Electrode 20 and Through portion 22

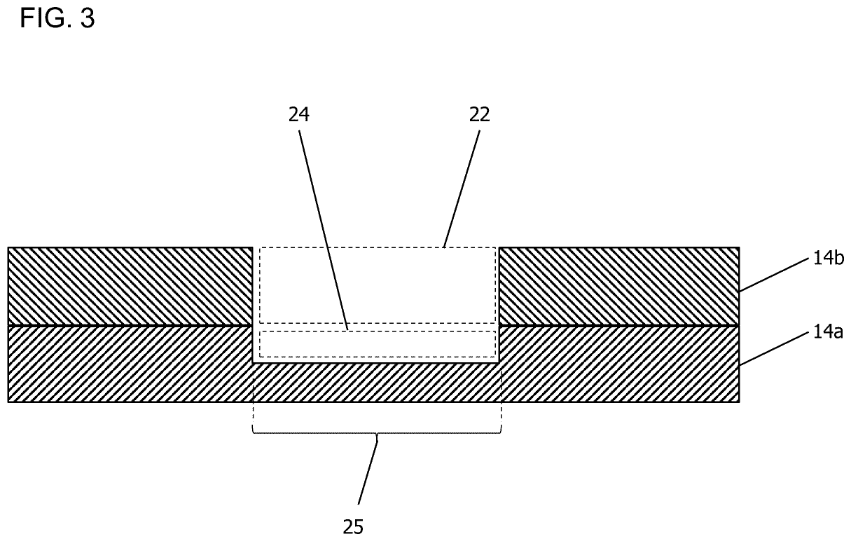

FIG. 3 is a cross sectional view of the first protective layer 14a and the second protective layer 14b in the vicinity of the gate electrode 20.

A portion of the gate electrode 20 (see FIG. 2) is arranged in a through portion 22 that penetrates through the second protective layer 14b (see FIG. 3). A portion 25 of the first protective layer 14a is arranged under such a through portion 22.

In the example depicted in FIG. 3, a portion of the gate electrode 20 is arranged in the through portion 22. However, when the first protective layer 14a does not have a dent 24 (see “(1-9)” and “5-5)”), the whole of the gate electrode 20 may be arranged in the through portion 22.

Incidentally, the term “through portion” represents an area that penetrates through an object (e.g., the second protective layer 14b), and is a portion of an outer area (i.e., the outside) of the object (for example, “through-hole” is a through-hole or slit).

### (1-9) Etching Resistance of First Insulator

The first insulator (i.e., the first protective layer 14a) is an insulator that is more difficult to remove by dry etching than the second insulator (i.e., the second protective layer 14b). Namely, the first insulator is an insulator that is etched more slowly than the second insulator when it is etched together with the second insulator by dry etching.

The through portion 22 of the second protective layer 14b (see FIG. 3) is typically formed by dry etching with large anisotropy. However, it is difficult to stop dry etching at the same time as completion of the through portion 22. For this reason, the first protective layer 14a is also etched for a certain time.

Accordingly, a dent 24 is formed in the first protective layer 14a. However, it hardly happens that a through portion is also formed in the first protective layer 14a, and thereby the gate electrode 20 comes in contact with the barrier layer 12. This is because the etching rate of the first protective layer 14a is slow. Therefore, the yield of the nitride transistor 2 in accordance with Embodiment 1, which has the first protective layer 14a, is high.

The reason why it is difficult to stop dry etching at the same time as the completion of the through portion 22 is that it is difficult to determine the highly precise and correct etching rate, and so on. Furthermore, other than this problem, dry etching has another problem that the etching rate varies depending on the position of the object to be etched on its surface (so-called in-plane distribution of the etching rate).

This another problem may also be solved by the first protective layer 14a with a slow etching rate. For this reason, the yield of the nitride transistor 2 in accordance with Embodiment 1 becomes further higher (see “(4-2) Comparative Example 2”).

It is noted that the term “dry etching” in the wording “an insulator that is more difficult to remove by dry etching” or other wordings means not dry etching in general but a certain dry etching. For example, the term “sry etching” means a dry etching where an insulator is etched by a plasma of a fluorine type gas (e.g., CF₄ gas) or a chlorine type gas (e.g., Cl₂ gas). Further, the term “etching rate of the first protective layer 14a” means the thickness of the first protective layer 14a to decrease in a unit time by etching. The same also applies to the term “etching rate of the second protective layer 14b” described later, or other terms.

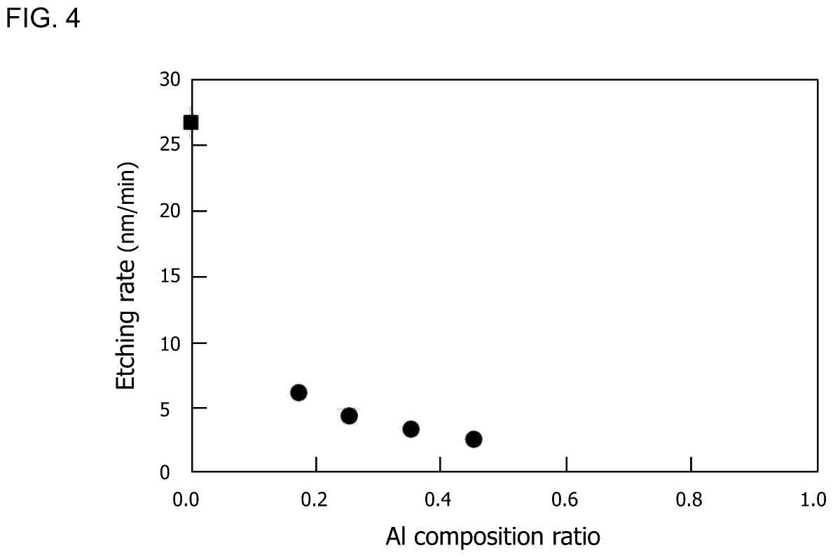

FIG. 4 is a view comparing the etching rates of SiAlN and SiN. The vertical axis represents the etching rate of dry etching using a fluorine type gas.

The horizontal axis represents the ratio CR_{Al} (=N_{Al}/(N_{Si}+N_{Al})) for the number N_{Al} of Al atoms in the SiAlN to the sum (=N_{Si}+N_{Al}) of the number N_{Si} of Si atoms in the SiAlN and the above number N_{Al} of the Al atoms (note that “Al atoms” means atoms of Al, and “Si atoms” means atoms of Si). The ratio CR_{Al} will be hereinafter referred to as the Al composition ratio. The data point on the vertical axis (i.e., the data point at which the Al composition ratio is zero) is the etching rate of SiN.

As represented in FIG. 4, the etching rate of SiAlN becomes ¼ or less the etching rate of SiN only by an increase in the Al composition ratio CR_{Al} from 0 to 0.17. When the Al composition ratio CR_{Al} further increases to 0.45, the etching rate of SiAlN becomes 1/10 the etching rate of SiN or less.

When the etching rate of the first protective layer 14a is ¼ or less the etching rate of the second protective layer 14b, it is easy to stop the dry etching for forming a through portion, at the first protective layer 14a. Therefore, when the first protective layer 14a is SiAlN and the second protective layer 14b is SiN, the yield of the nitride transistor 2 becomes sufficiently high. For this reason, in the foregoing case, the Al composition ratio CR_{Al} of the first protective layer 14a is preferably 0.17 or more.

However, SiAlN becomes more likely to be crystallized when the Al composition ratio CR_{Al} becomes more than 0.5. As described above, when an insulator is crystallized, the resistance value thereof is reduced. For this reason, the Al composition ratio CR_{Al} of SiAlN for use as the first protective layer 14a is preferably 0.5 or less. Therefore, the Al composition ratio CR_{Al} of the first protective layer 14a is preferably 0.17 or more and 0.5 or less.

In other words, when the first protective layer 14a is SiAlN, and the second protective layer 14b is SiN, the first number of Al atoms possessed by the first protective layer 14a is preferably 0.17 times or more and 0.5 times or less the sum of a second number of Si atoms possessed by the first protective layer 14a and the above first number of Al atoms. Further preferably, the first number of atoms is 0.2 times or more and 0.45 times or less the sum of the second number of atoms and the first number of atoms. Most preferably, the first number of atoms is 0.25 times or more and 0.4 times or less the sum of the second number of atoms and the first number of atoms.

### (1-10) Advantage of Having First Protective Layer 14a

As represented in FIG. 2, the lower part of the gate electrode 20 of the nitride transistor 2 is arranged not in a through portion that penetrates through the passivation film on the barrier layer (see “(4-1) Comparative Example 1”), but in the through portion 22 on the first protective layer 14a.

Incidentally, a through portion of passivation film is typically formed by dry etching with large anisotropy. If the barrier layer 12 is exposed to the plasma generated during dry etching, the density and the mobility of the two dimensional electron gas generated in the channel layer 8 decrease, which makes it difficult to increase the output power and the operating frequency of the nitride transistor. The reason why the two dimensional electron gas in the channel layer, which is arranged under a barrier layer and thereby is not exposed to the plasma, deteriorates in this case is not yet understood. Here, the deterioration of the two dimensional electron gas is, in particular, the decrease in its density and its mobility.

However, in Embodiment 1, the through portion 22, where the lower part of the gate electrode 20 is arranged, is situated on the first protective layer 14a. For this reason, the barrier layer 12 will not be exposed to a plasma during the formation of the through portion 22 by dry etching. Therefore, according to Embodiment 1, the density and the mobility of the two dimensional electron gas of the channel layer 8 is not reduced due to plasma exposure of the barrier layer 12.

Further, as described above, the first protective layer 14a is less likely to be etched than the second protective layer 14b. For this reason, according to Embodiment 1, the yield of a nitride transistor in which a gate electrode is arranged at a through portion becomes higher (see “(1-9)”). Therefore, according to Embodiment 1, it is possible to provide a nitride transistor that enables increased output power and increased operating frequency, and to do so with a high yield.

### (1-11) Others

In the example depicted in FIG. 2, the first protective layer 14a is in contact with the barrier layer 12, and the gate electrode 20 is in contact with the first protective layer 14a under the through portion 22. Such first protective layer 14a and gate electrode 20 minimize the layer that is interposed between the gate electrode 20 and the channel layer 8. For this reason, the space between the gate electrode 20 and the channel layer 8 is narrowed, and the mutual conductance of the nitride transistor 2 increases.

In the example depicted in FIG. 2, the first protective layer 14a has a dent 24 under the through portion 22 (see FIG. 3). Therefore, the lowermost part of the gate electrode 20 is arranged in such a dent 24.

However, the first protective layer 14a may not to have such a dent. For example, when the through portion 22 is formed by just etching of the second protective layer 14b, the dent 24 is not formed in the first protective layer 14a.

### (2) Generation of Two Dimensional Electron Gas and Suppression of Current Collapse

### (2-1) Generation of Two Dimensional Electron Gas

The barrier layer 12 and the channel layer 8 are configured such that a two dimensional electron gas is generated in the channel layer 8.

Herein, a description will be given to the case where the nitride transistor 2 does not have the spacer layer 10. However, even when the nitride transistor 2 has the spacer layer 10, the following description holds as it is.

The channel layer 8 is, for example, a GaN layer (i.e., a GaN channel layer) arranged so that the upper surface thereof (i.e., the surface on the first protective layer 14a side) is a metal surface. The barrier layer 12 is, for example, an InAlGaN layer that has Al and In compositions set as described later, and is arranged so that the upper surface thereof (i.e., the surface on the first protective layer 14a side) is a metal surface.

For the InAlGaN layer that has a metal surface on the upper surface thereof, spontaneous polarization from the upper surface thereof toward the lower surface thereof (i.e., the surface on the substrate 4 side) is generated. This spontaneous polarization generates a positive polarization electric charge on the lower surface of the InAlGaN barrier layer.

In the GaN channel layer, this positive polarization electric charge forms a potential that decreases toward the upper surface thereof. This potential and the forbidden band of the barrier layer 12 form a potential well that has a triangular profile (which will be hereinafter referred to as a triangle potential) in the vicinity of the upper surface of the GaN channel layer. When this potential well is sufficiently deep, a two dimensional electron gas is generated in the GaN channel layer.

The triangle potential of the GaN channel layer becomes deeper with an increase in positive polarization electric charge on the lower surface of the InAlGaN barrier layer. Then, the positive polarization electric charge on the lower surface of the InAlGaN barrier layer increases with an increase in the Al composition of the InAlGaN barrier layer. Thus, the Al composition of the InAlGaN barrier layer is set large enough to generate a two dimensional electron gas in the GaN channel layer.

However, the lattice mismatch between the GaN channel layer and the InAlGaN barrier layer increases with an increase in the Al composition of the InAlGaN barrier layer. Thus, the In composition of the InAlGaN barrier layer is set so that the decrease of the lattice constant due to an increase in the Al composition is suppressed by the increase in the lattice constant due to an increase in the In composition.

Such suppression of the lattice mismatch is difficult for the AlGaN barrier layer that does not include In as a constituent element. For this reason, the InAlGaN barrier layer enables generation of a high density two dimensional electron gas, which is difficult to achieve with the AlGaN barrier layer.

### (2-2) Suppression of Current Collapse

The first protective layer 14a and the second protective layer 14b are configured such as to suppress current collapse.

Specifically, the first protective layer 14a is, for example, SiAlN (e.g., SiAlN with a thickness of 4 nm) grown following the barrier layer 12 in an apparatus in which the barrier layer 12 has been grown (i.e., in situ) (see “(5) manufacturing method”). The second protective layer 14b is, for example, SiN (e.g., SiN with a thickness of 40 nm) grown following the first protective layer 14a in the apparatus in which the first protective layer 14a has been grown (i.e., in situ), and thicker than the first protective layer 14a.

The current collapse is the following phenomenon: when a large current flows to a nitride transistor with the drain electrode applied with a high voltage, the drain current decreases temporarily.

The current collapse may be suppressed by covering the barrier layer with a passivation film of SiN or the like. However, when the passivation film is thin, it is difficult to suppress the current collapse. Therefore, for the second protective layer 14b, SiN thicker than the first protective layer 14a or the like is used.

Although the mechanism by which the current collapse is caused has not been clear even now, it is possible to suppress the current collapse by growing a passivation film (specifically, an insulator layer) following the barrier layer in an apparatus in which the barrier layer has been grown. From this fact, it may be considered that the current collapse is caused due to the following: exposure of the barrier layer surface to the atmosphere generates surface levels, and electrons running at a high speed at the channel layer are captured by the surface levels, resulting in a shallow potential well in the vicinity of the upper surface of the channel layer.

However, such a description is hypothesis, and the cause of the current collapse has not been revealed. Therefore, it is currently difficult to identify the structures of the “first protective layer 14a and the second protective layer 14b” configured so as to suppress the current collapse. However, it is possible to identify the “first protective layer 14a and the second protective layer 14b” by the manufacturing method thereof (i.e., growth in situ).

### (3) Operation

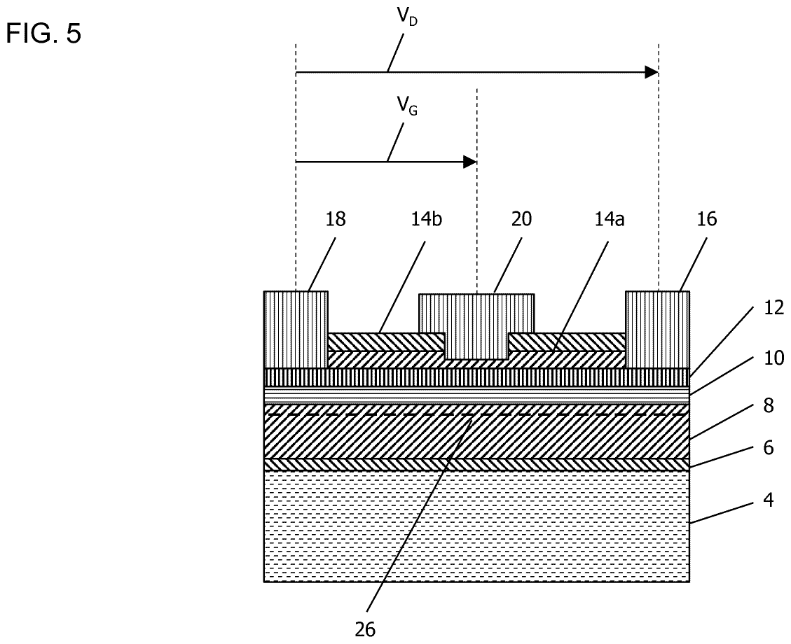

FIG. 5 is a view for illustrating one example of the operation of the nitride transistor 2.

V_{G} (which will be hereinafter referred to as a gate voltage) is the potential difference (=Φg-Φs) between the potential Φg of the gate electrode 20 and the potential Φs of the source electrode 18. V_{D} (which will be hereinafter referred to as a drain voltage) is the potential difference (=Φd-Φs) between the potential Φd of the drain electrode 16 and the potential Φs of the source electrode 18.

When the gate voltage V_{G} is 0 V, a two dimensional electron gas 26 (i.e., the group of electrons in the conduction band) is localized in the part of the channel layer 8 that is in contact with the spacer layer 10. The two dimensional electron gas 26 is present in the area from immediately under the source electrode 18 to immediately under the drain electrode 16.

When the positive drain voltage V_{D} is applied to the drain electrode 16 in this state, the two dimensional electron gas 26 moves from the source electrode 18 toward the drain electrode 16 at a high speed. As a result, a current that flows into the drain electrode 16, flows through the channel layer 8, and flows out of the source electrode 18 (which will be hereinafter referred to as a drain current) is generated in the nitride transistor 2.

When the gate voltage V_{G} becomes a negative voltage, the conduction band end Ec increases at the interface between the channel layer 8 and the spacer layer 10 (which will be hereinafter referred to as a heterointerface). Then, the triangle potential in contact with the heterointerface becomes shallow at the channel layer 8 immediately under the gate electrode 20. As a result, the density of the two dimensional electron gas 26 decreases immediately under the gate electrode 20, and the drain current decreases.

When the gate voltage V_{G} further decreases, and becomes equal to or lower than the threshold value, the two dimensional electron gas vanishes immediately under the gate electrode 20, so that the nitride transistor 2 is rendered in a non-conduction state (i.e., the OFF state).

On the other hand, when the gate voltage V_{G} becomes a positive voltage, the conduction band end Ec descends at the heterointerface. Then, the triangle potential in contact with the heterointerface becomes deep at the channel layer 8 immediately under the gate electrode 20. As a result, immediately under the gate electrode 20, the density of the two dimensional electron gas 26 increases, and the drain current increases.

Namely, the nitride transistor 2 is a transistor with a drain current varying according to the gate voltage V_{G} (i.e., the nitride transistor 2 is a field effect transistor).

In the description up to this point, the nitride transistor 2 is a transistor that has a normally on characteristic. However, the nitride transistor 2 may be a transistor that has a normally off characteristic.

### (4) Comparative Examples

### (4-1) Comparative Example 1

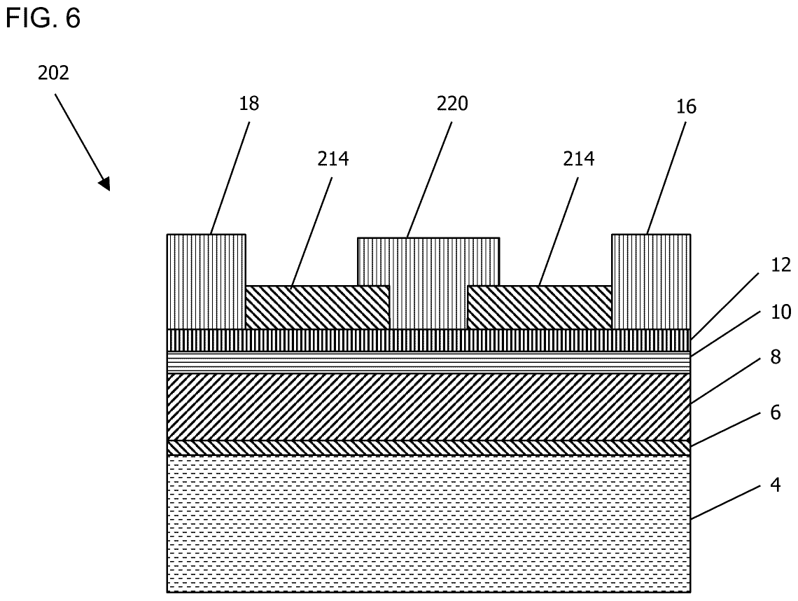

FIG. 6 is a cross sectional view of a nitride transistor 202 (which is referred to as Comparative Example 1 where appropriate) that has a SiN layer 214 in place of the first protective layer 14a (see FIG. 2) and the second protective layer 14b. The SiN layer 214 is a passivation film that has through portion where a portion of the gate electrode 220 is arranged.

The nitride transistor 202 has the barrier layer 12 covered with the SiN layer 214. For this reason, the nitride transistor 202 may suppress the current collapse. The same also applies to Comparative Examples 2 and 4.

The through portion of the passivation film is typically formed by dry etching with large anisotropy. However, it is difficult to stop dry etching at the same time as the completion of the through portion of the passivation film. For this reason, the upper surface of the barrier layer 12 is also etched to a certain degree. At this step, the upper surface of the barrier layer 12 is exposed to a plasma generated during dry etching.

The plasma exposure reduces the density and the mobility of the two dimensional electron gas at the channel layer 8 immediately under the through portion. As a result, the drain current of the nitride transistor 202 decreases.

Therefore, it is difficult to increase the output power of the nitride transistor 202. Further, the reduction of the mobility of the two dimensional electron gas makes it difficult to achieve the high frequency response of the nitride transistor 202.

On the other hand, the nitride transistor 2 in accordance with Embodiment 1 does not have a through portion reaching the barrier layer 12. Therefore, the barrier layer 12 will not be exposed to a plasma. For this reason, according to Embodiment 1, it becomes possible to achieve the high output power and the high frequency response of the nitride transistor.

Specifically, the output power of the nitride transistor 2 according to Embodiment 1 becomes about 1.12 times the output power of, for example, the nitride transistor 202 (i.e., Comparative Example 1).

### (4-2) Comparative Example 2

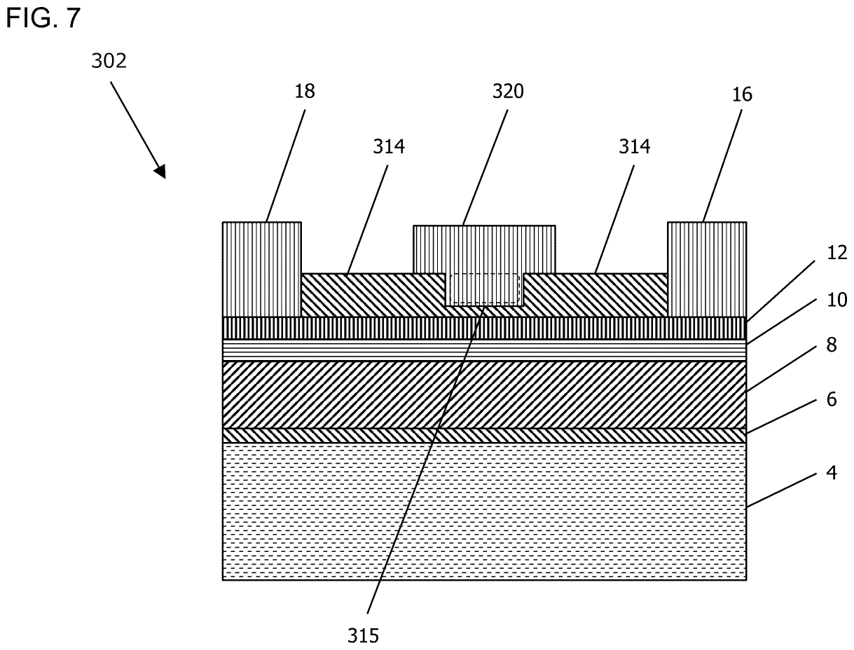

FIG. 7 is a cross sectional view of a nitride transistor 302 (which is referred to as Comparative Example 2 where appropriate) that has a SiN layer 314 with a dent 315 in place of the first protective layer 14a and the second protective layer 14b (see FIG. 2). The lower part of the gate electrode 320 is arranged in the dent 315.

For the formation of the dent 315, dry etching with large anisotropy is suitable. However, dry etching has a problem that the etching rate varies according to the position on the surface of the insulator to be etched (which will be hereinafter referred to as an in-plane position). For this reason, when a plurality of nitride transistors 302 are formed on the same substrate, nitride transistors 202 each of which has not a dent but a through portion at the SiN layer (i.e., Comparative Example 1) are also formed.

Dry etching further has another following problem: a highly precise and correct etching rate is difficult to decide, and hence when the depth of the dent 315 is controlled by the time of etching, not a dent but a through portion may be formed. Because of the problems, the yield of the nitride transistor 302 (i.e., Comparative Example 2) is low.

On the other hand, according to Embodiment 1, the first protective layer 14a, which is more difficult to etch than the second protective layer 14b, is arranged under the second protective layer 14b (see FIG. 2). Therefore, the through portion 22 of the second protective layer 14b rarely penetrates through the first protective layer 14a, and rarely reaches the barrier layer 12. For this reason, the yield of the nitride transistor 2 according to Embodiment 1 is high.

### (4-3) Comparative Example 3

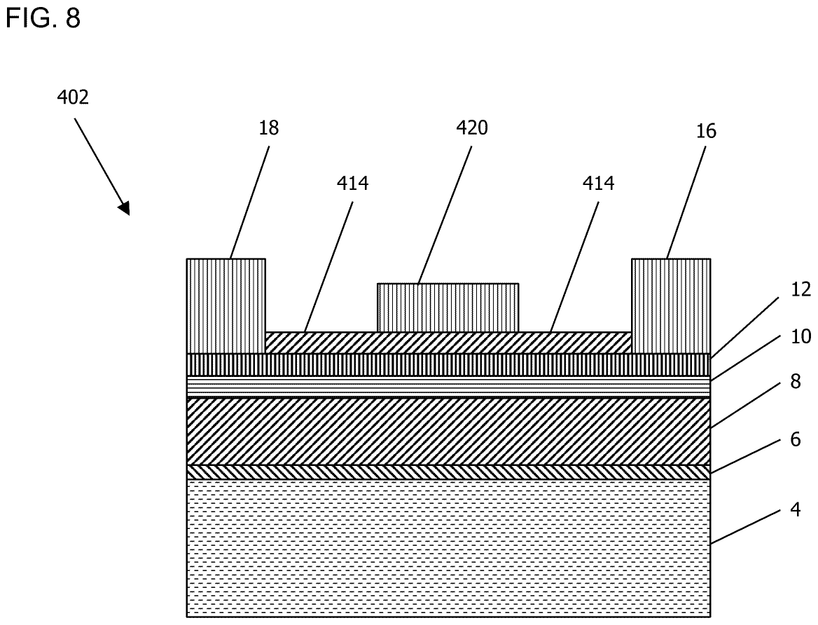

FIG. 8 is a cross sectional view of a nitride transistor 402 (which is referred to as Comparative Example 3 where appropriate) that has a thin SiAlN layer 414 in place of the first protective layer 14a (see FIG. 2) and the second protective layer 14b.

The gate electrode 420 of the nitride transistor 402 is arranged not in the through portion or the dent, but on the SiAlN layer 414. Therefore, the nitride transistor 402 does not have a problem that the yield is reduced by dry etching for forming the through portion or the dent.

However, the nitride transistor 402 has the following problem. The passivation film (i.e., the SiAlN layer 414) that covers the barrier layer 12 is thin; for this reason, the suppression of current collapse is insufficient.

On the other hand, the nitride transistor 2 according to Embodiment 1 has a thick second protective layer 14b (e.g., the SiN layer) on the first protective layer 14a (e.g., the thin SiAlN layer).

Therefore, in accordance with Embodiment 1, it is possible to sufficiently suppress the current collapse.

### (4-4) Comparative Example 4

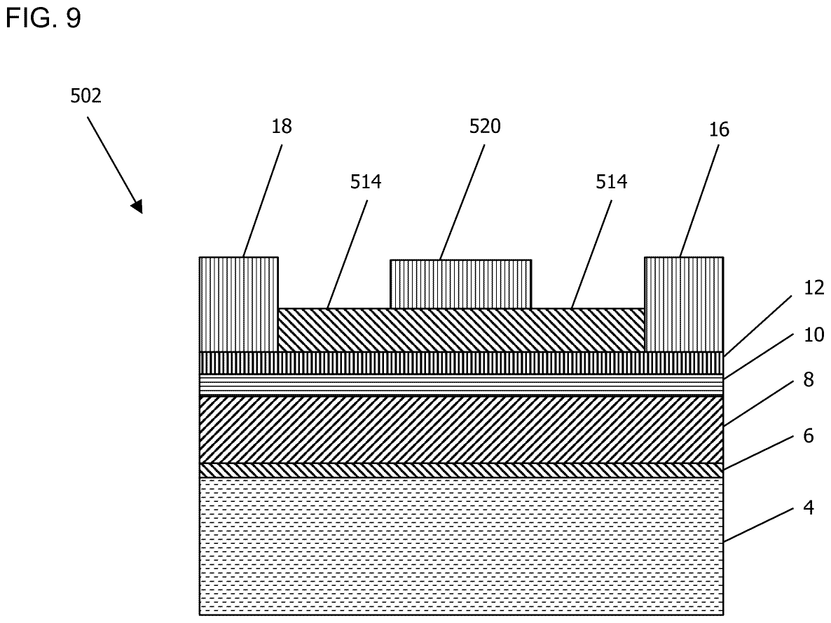

FIG. 9 is a cross sectional view of a nitride transistor 502 (which is referred to as Comparative Example 4 where appropriate) that has a sufficiently thick SiN layer 514 in place of the first protective layer 14a (see FIG. 2) and the second protective layer 14b.

In the nitride transistor 502, the gate electrode 520 is arranged not in the through portion or the dent but on the SiN layer 514. Therefore, the nitride transistor 502 does not have a problem that dry etching for forming the through portion or the dent reduces the yield. In addition, the barrier layer 12 of the nitride transistor 502 is covered with the thick SiN layer 514. For this reason, the nitride transistor 502 also has no problem that the suppression of current collapse is insufficient.

However, in the nitride transistor 502, the thick SiN layer 514 is present between the barrier layer 12 and the gate electrode 520. For this reason, the nitride transistor 502 (i.e., Comparative Example 4) has a problem of a low mutual conductance.

On the other hand, for the nitride transistor 2 according to Embodiment 1, the object for separating the barrier layer 12 and the gate electrode 20 is only the thin first protective layer 14a. Therefore, according to Embodiment 1, the mutual conductance may be increased.

### (5) Manufacturing Method

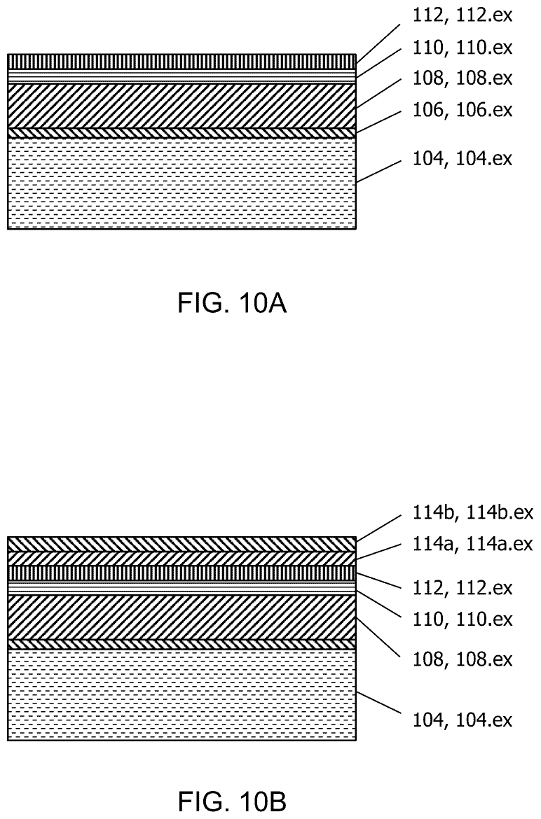

FIGS. 10A to 12B are each a process cross-sectional view depicting one example of a method for manufacturing the nitride transistor 2.

### (5-1) Growth of nitride semiconductor layer (see FIG. 10A)

First, on the substrate 104, an AlN nucleation layer 106, a channel layer 108, a spacer layer 110, and a barrier layer 112 are formed in this order. The channel layer 108 is a layer of a first nitride semiconductor. The barrier layer 112 is a layer of a second nitride semiconductor with a wider bandgap than that of the first nitride semiconductor. The barrier layer 112 generates a two dimensional electron gas in the channel layer 108. The growth of the AlN nucleation layer 106 and the spacer layer 110 may be omitted (see “(1-1)” and “(1-3)” of “(1) Structure”).

Specifically, for example, on the (0001) plane of a semi-insulating SiC substrate 104.ex (see FIG. 10A), an AlN nucleation layer 106.ex is grown by a metal organic chemical vapor deposition. The raw material gas is, for example, a mixed gas of a trimethyl aluminum (which will be hereinafter described as TMAl) gas and an ammonia (NH₃) gas.

The SiC substrate 104.ex is one example of the substrate 104. The AlN nucleation layer 106.ex is one example of the AlN nucleation layer 106. The same also applies to each layer and electrode (e.g., a channel layer 108.ex and a gate electrode 120.ex ) described later.

The carrier gas is a hydrogen (H₂) gas or a nitrogen (N₂) gas. During the growth of the AlN nucleation layer 106.ex, the temperature of the SiC substrate 104.ex (which will be hereinafter referred to as the growth temperature) is kept at, for example, 700° C. to 1200° C.

The pressure of the growth chamber where the SiC substrate 104.ex is placed (which will be hereinafter referred to as the growth chamber pressure) is kept at, for example, 1 kPa to 100 kPa during the growth of the AlN nucleation layer 106. The carrier gas, the growth temperature, and the growth chamber pressure are also kept within the above ranges for the subsequent growth of the channel layer 108, or the like.

Thereafter, on the AlN nucleation layer 106.ex, a GaN channel layer 108.ex is grown with the metal organic chemical vapor deposition. The raw material gas is, for example, a mixed gas of a trimethyl gallium (which will be hereinafter described as TMGa) gas and an ammonia (NH₃) gas.

Thereafter, on the GaN channel layer 108.ex, an AlGaN spacer layer 110.ex is grown by the metal organic chemical vapor deposition. The raw material gas is, for example, a mixed gas of a TMAl gas, a TMGa gas, and an ammonia (NH₃) gas.

Thereafter, on the AlGaN spacer layer 110.ex, an InAlGaN barrier layer 112.ex is grown by the metal organic chemical vapor deposition. The raw material gas is, for example, a mixed gas of a trimethyl indium gas, a TMAl gas, a TMGa gas, and an ammonia (NH₃) gas.

### (5-2) Growth of First and Second Protective Layers 114a and 114b (see FIG. 10B)

Then, a first protective layer 114a that is a first insulator, and a second protective layer 114b that is a layer of a second insulator and is thicker than the first protective layer 114a are formed on the barrier layer 112 in this order. The first insulator is an insulator that is more difficult to remove by a certain dry etching than the second insulator.

Specifically, first, on the InAlGaN barrier layer 112.ex, a SiAlN layer 114a.ex (one example of the first protective layer 114a) is grown with the metal organic chemical vapor deposition. The raw material gas is, for example, a mixed gas of a silane (SiH₄) gas, a TMAl gas, and an ammonia (NH₃) gas.

The thickness of the SiAlN layer 114a.ex is, for example, 4 nm. The thickness of the SiAlN layer 114a.ex is preferably 2 nm or more and 6 nm or less. Further preferably, the thickness of the SiAlN layer 114a.ex is 3 nm or more and 5 nm or less. The Al composition ratio of the SiAlN layer 114a.ex is preferably 0.17 or more and 0.5 or less (e.g., 0.45) (see “(1-9)” of “(1) Structure”).

Thereafter, on the SiAlN layer 114a.ex, a SiN layer 114b.ex (one example of the second protective layer 114b) thicker than the SiAlN layer 114a.ex is grown with the metal organic chemical vapor deposition. The raw material gas is, for example, a mixed gas of a silane (SiH₄) gas and an ammonia (NH₃) gas.

The thickness of the SiN layer 114b.ex is, for example, 40 nm. The total thickness of the SiAlN layer 114a.ex and the SiN layer 114b.ex is preferably 10 nm or more and 100 nm or less. Further preferably, the total thickness of the SiAlN layer 114a.ex and the SiN layer 114b.ex is 30 nm or more and 70 nm or less.

The growth of the SiAlN layer 114a.ex and the SiN layer 114b.ex is preferably performed following the growth of the InAlGaN barrier layer 112.ex in the apparatus where the InAlGaN barrier layer 112.ex, or the like has been grown (see “(2-2) Suppression of current collapse”).

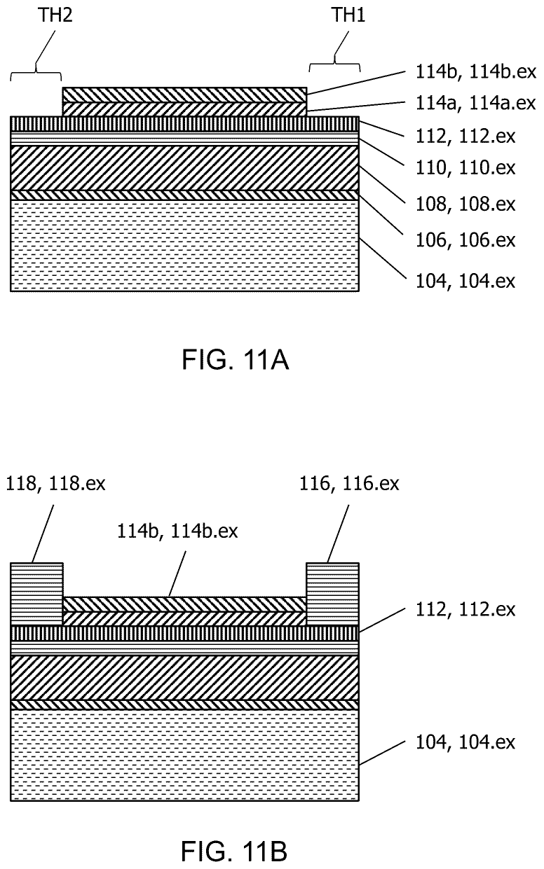

### (5-3) Formation of Drain Electrode 116 and Source Electrode 118 (see FIGS. 11A and 11B)

Then, a drain electrode 116 (see FIG. 11B) in ohmic contact with the barrier layer 112, and a source electrode 118 also in ohmic contact with the barrier layer 112 are formed.

Specifically, first, a photoresist film (not depicted) that has a grid-like or frame-like opening is formed on the SiN layer 114b.ex (see FIG. 10B). Subsequently, each layer formed on the SiC substrate 104.ex is etched via the opening, thereby forming an element isolation groove (not depicted). Etching is performed by, for example, dry etching. The etching gas is, for example, a chlorine type gas.

In place of the element isolation groove, an element isolation area may be formed by increasing the resistance of each semiconductor layer grown on the SiC substrate 104.ex by, for example, ion implantation via the opening of the photoresist film.

Subsequently, a photoresist film (not depicted) that has a rectangular opening and another rectangular opening extending along the long side of the rectangular opening is formed on the SiN layer 114b.ex., provided that the photoresist film is formed such that the two openings are arranged inside of the element isolation groove.

Subsequently, the SiN layer 114b.ex and the SiAlN layer 114a.ex are etched via the two openings, thereby forming through holes TH1 and TH2 that penetrates through the SiN layer 114b.ex and the SiAlN layer 114a.ex (see FIG. 11A) The etching is performed, for example, by dry etching. The etching gas is, for example, a fluorine type gas or a chlorine type gas.

Subsequently, inside the through holes TH1 and TH2 as well as on the photoresist film, a Ta layer with a thickness of 10 nm-40 nm (e.g., 20 nm), and an Al layer with a thickness of 100 nm-400 nm (e.g., 200 nm) are vacuum evaporated in this order. Subsequently, the Ta layer and the Al layer on the photoresist film are removed together with the photoresist film. As a result of this, a metal layer that has the Ta layer and the Al layer in this order (which will be hereinafter referred to as a Ta/Al vacuum evaporation layer) are left inside the through holes TH1 and TH2.

Subsequently, the SiC substrate 104.ex, on which the Ta/Al vacuum evaporation layer is formed, is subjected to a heat treatment at 400°C.-1000°C. (e.g., 550° C.). As a result, a drain electrode 116.ex in ohmic contact with the InAlGaN barrier layer 112.ex and a source electrode 118.ex similarly in ohmic contact with the InAlGaN barrier layer 112.ex are formed from the Ta/Al vacuum evaporation layer inside the through holes TH1 and TH2.

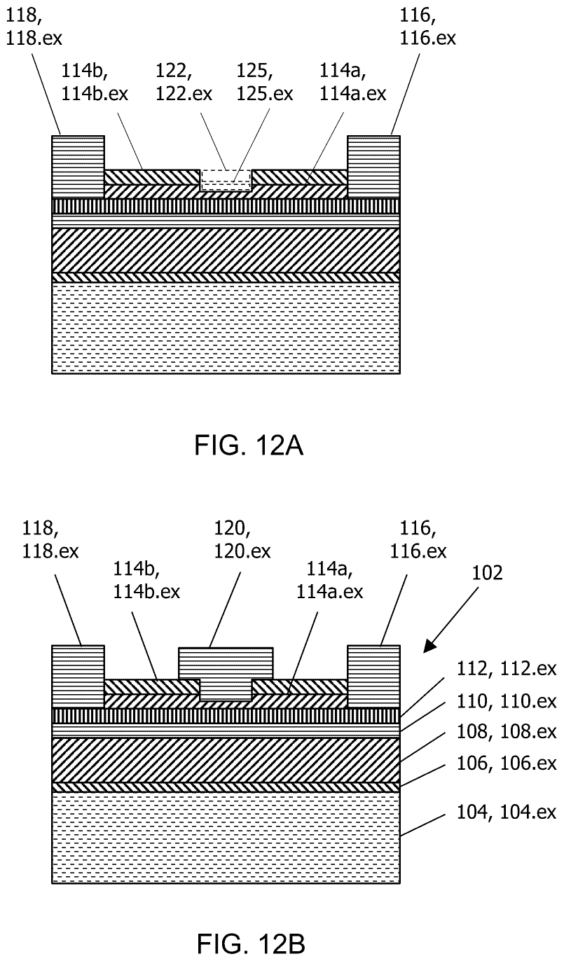

### (5-4) Formation of Through Portion 122 (see FIG. 12A)

Then, a portion of the second protective layer 114b (see FIG. 11B) is etched, thereby forming a through portion 122 (see FIG. 12A) that penetrates through the second protective layer 114b between the drain electrode 116 and the source electrode 118.

Specifically, first, a photoresist film (not depicted) that has a rectangular opening is formed between the drain electrode 116.ex (see FIG. 11B) and the source electrode 118.ex.

Subsequently, the SiN layer 114b.ex is etched via the opening, thereby forming a through portion 122.ex that penetrates through the SiN layer 114b.ex (see FIG. 12A). At this step, the SiAlN layer 114a.ex is also slightly etched, resulting in the formation of a dent 125.ex (one example of the dent 24 depicted in FIG. 3).

Etching is performed by, for example, dry etching. The etching gas is, for example, a fluorine type gas. The etching conditions (e.g., the high frequency electric power for generating a plasma) are the same as the etching conditions used for acquiring data of FIG. 4.

Even after an elapse of the etching time at which the completion of the through portion 122.ex is expected, a certain degree of etching is continued in order to ensure the completion of the through portion. For this reason, a dent 125.ex is formed in the SiAlN layer 114a.ex. However, the SiAlN layer 114a.ex is more difficult to etch than the SiN layer 114b.ex. For this reason, a through portion that penetrates through the SiAlN layer 114a.ex will not be formed.

### (5-5) Formation of Gate Electrode 120 (see FIG. 12B)

Finally, a gate electrode 120 (see FIG. 12B) partially arranged in the through portion 122 (see FIG. 12A) is formed.

However, although it is rare, when the dent 125 is not formed in the first protective layer 114a (see FIG. 12A), the whole of the gate electrode 120 may be formed at the through portion 122.

Specifically, first, formed is a photoresist film that has an opening on the through portion 122.ex. Then, on the photoresist film and inside the opening, a Ni layer with a thickness of 15 nm-60 nm (e.g., 30 nm) and an Au layer with a thickness of 200 nm-800 nm (e.g., 400 nm) are vacuum evaporated in this order. Subsequently, the Ni layer and the Au layer on the photoresist film are removed together with the photoresist film. As a result of this, formed is a gate electrode 120.ex (see FIG. 12B) that has the Ni layer and the Au layer in this order.

By the procedures up to this point, a nitride transistor 102 is completed. The nitride transistor 102 is one example of the nitride transistor 2 depicted in FIG. 2. The first protective layer 114a of the completed nitride transistor 102 is one example of the first protective layer 14a depicted in FIG. 2. The same also applies to other members (e.g., the second protective layer 114b and the barrier layer 112) of the nitride transistor 102. The same also applies to the manufacturing method according to Embodiment 2 described later.

### (6) Modified Example

The nitride transistor 2 described by reference to FIGS. 1-2 and the like has a gate electrode 20 in contact with the first protective layer 14a. However, the nitride transistor according to Embodiment 1 may have a gate electrode isolated from the first protective layer 14a.

For example, the nitride transistor according to Embodiment 1 may have a gate electrode isolated from the first protective layer 14a by a thin insulation film covering the side surfaces of the through portion 22 (see FIG. 3) and the dent 24, and the bottom surface of the dent 24. In accordance with this Modified Example, even when the insulating property of the first protective layer 14a is insufficient, it is possible to suppress the gate leakage current with reliability.

Similarly, the nitride transistor according to Embodiment 1 may have the first protective layer 14a isolated from the barrier layer 12. For example, a thin insulator layer may be arranged between the first protective layer 14a and the barrier layer 12.

The gate electrode 20 according to Embodiment 1 is arranged not in the through portion of the passivation film in contact with the barrier layer 12, but in the through portion 22 of the second protective layer 14b on the first protective layer 14a. Therefore, the barrier layer 12 is not exposed to the plasma generated during dry etching for forming the through portion. Therefore, in accordance with Embodiment 1, it is possible to suppress the reduction of the density and the mobility of the two dimensional electron gas by dry etching for forming the through portion. For this reason, it is possible to achieve the high output power and the high frequency response of the nitride transistor.

Further, the first protective layer 14a is more difficult to etch than the second protective layer 14b. For this reason, the through portion rarely penetrates through the first protective layer 14a, and reaches the barrier layer 12. Therefore, the yield of the nitride transistor according to Embodiment 1 is high.

Therefore, in accordance with Embodiment 1, it is possible to provide a nitride transistor that achieve the high output power and the high frequency response, and has a high yield.

### Embodiment 2

Embodiment 2 is similar to Embodiment 1. Therefore, the description regarding the parts in common with Embodiment 1 will be omitted or simplified.

### (1) Structure

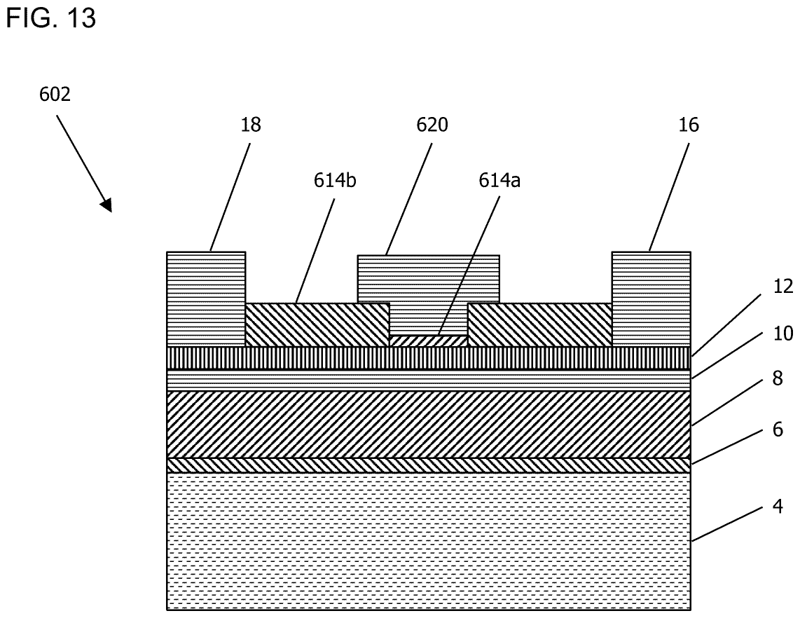

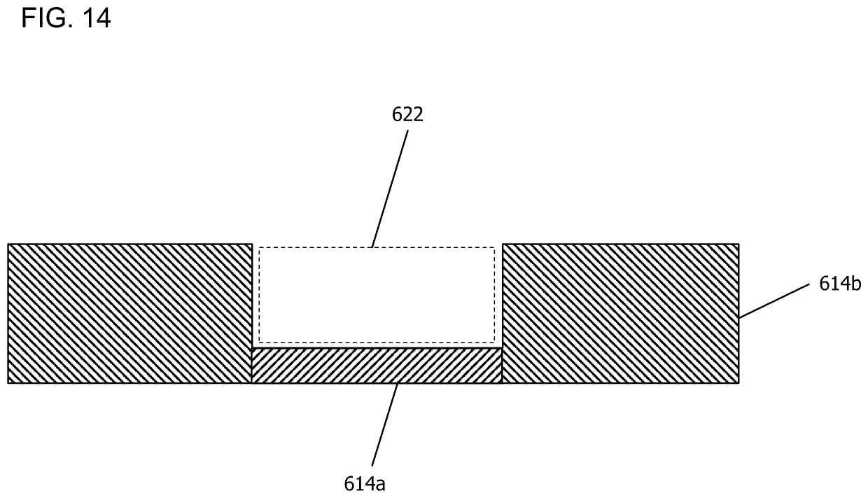

FIG. 13 is a cross sectional view of one example 602 of a semiconductor device in accordance with Embodiment 2 (which will be hereinafter referred to as a nitride transistor). FIG. 14 is a cross sectional view of the first protective layer 614a and the second protective layer 614b in the vicinity of the gate electrode 620.

As depicted in FIG. 13, the nitride transistor 602 according to Embodiment 2 has first and second protective layers 614a and 614b different in structure and position from the first and second protective layers 14a and 14b according to Embodiment 1.

### (1-1) First and Second Protective Layers 614a and 614b

As represented in FIG. 13, the first protective layer 614a is arranged between the drain electrode 16 and the source electrode 18, and is isolated from the drain electrode 16 and the source electrode 18.

The second protective layer 614b is arranged on the barrier layer 12, without the first protective layer 614a in between (precisely, without the first protective layer 614a being sandwiched between the barrier layer 12 and the second protective layer 614a). The first protective layer 614a is arranged in the through portion 622 (see FIG. 14) that penetrates through the second protective layer 614b.

### (1-2) Gate Electrode 620

As depicted in FIG. 13, a portion of the gate electrode 620 (which will be hereinafter referred to as a gate buried portion) is arranged so as to be situated on the first protective layer 614a in the through portion 622 (see FIG. 14). However, the gate electrode 620 may be entirely arranged in the through portion 622.

Except for these points, the nitride transistor 602 according to Embodiment 2 has substantially the same structure as that of the nitride transistor 2 according to Embodiment 1.

### (2) Manufacturing Method

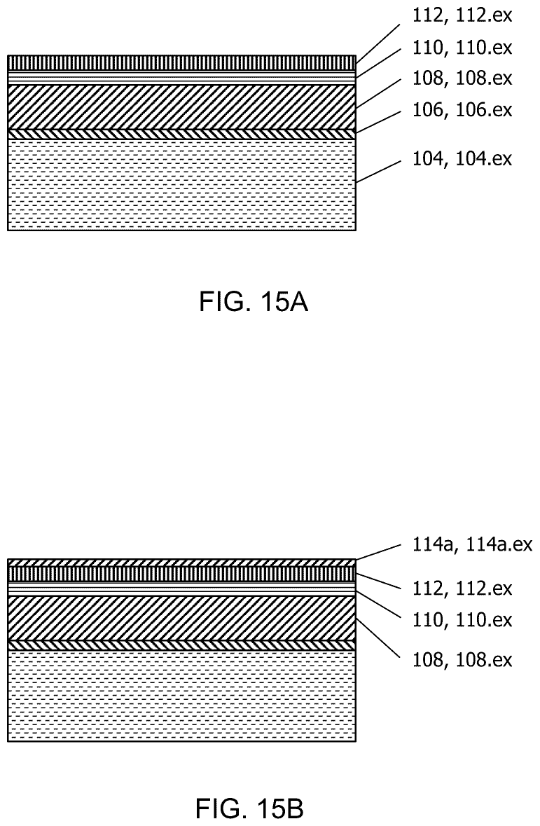

FIGS. 15A to 18B are each a process cross-sectional view illustrating one example of the method for manufacturing the nitride transistor 602. The method for manufacturing the nitride transistor 602 according to Embodiment 2 is similar to the method for manufacturing the nitride transistor 2 according to Embodiment 1.

The description regarding the parts in common with the manufacturing method according to Embodiment 1 will be omitted or simplified.

### (2-1) Growth of Nitride Semiconductor Layer (see FIG. 15A)

First, on the substrate 104, the AlN nucleation layer 106, the channel layer 108 that is a first nitride semiconductor, the spacer layer 110, and the barrier layer 112 that is a second nitride semiconductor with a wider bandgap than that of the first nitride semiconductor are formed in this order (see FIG. 15A).

Specifically, on the semi-insulating SiC substrate 104.ex, the AlN nucleation layer 106.ex, the GaN channel layer 108.ex, the AlGaN spacer layer 110.ex, and the InAlGaN barrier layer 112.ex are grown according to the procedure described in Embodiment 1.

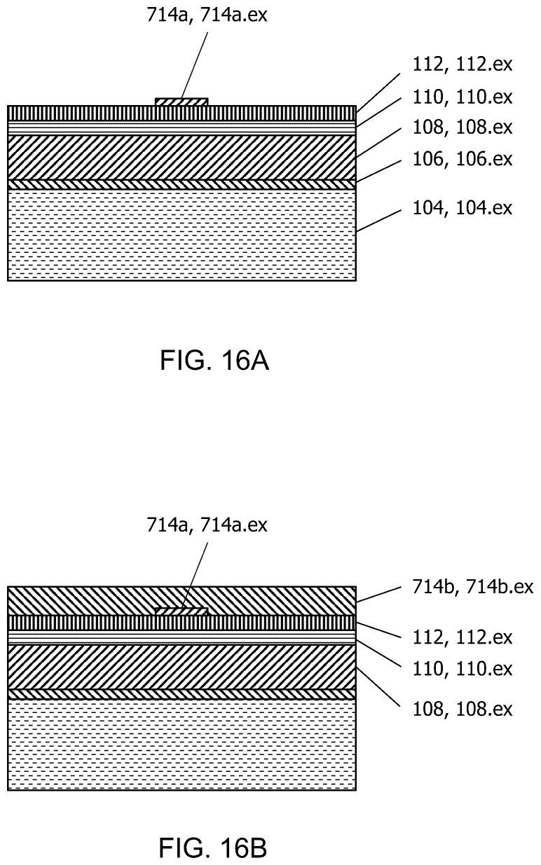

### (2-2) Formation of First Protective Layer 714a (see FIGS. 15B to 16A)

Then, on the barrier layer 112, formed is an island-shaped first protective layer 714a (see FIG. 16A) that is a layer of a first insulator. The first insulator is an insulator that is more difficult to remove by a certain dry etching than a second insulator described later.

Specifically, first, according to the procedure described in Embodiment 1, a SiAlN layer 114a.ex is grown (see FIG. 15B). The thickness of the SiAlN layer 114a.ex is, for example, 2 nm. The Al composition ratio of the SiAlN layer 114a.ex is, for example, 0.34. The preferable ranges of the thickness and the Al composition ratio of the SiAlN layer 114a.ex are as indicated in Embodiment 1.

Then, a rectangular photoresist film (not depicted) is formed on the SiAlN layer 114a.ex.Subsequently, the SiAlN layer 114a.ex is etched via the photoresist film, for example by wet etching, which does not cause a plasma. As a result, an island-shaped SiAlN layer 714a.ex (see FIG. 16A) is formed. The island-shaped SiAlN layer 714a.ex is one example of the first protective layer 714a.

### (2-3) Formation of Second Protective Layer 714b (see FIG. 16B)

Then, on the barrier layer 112 and the first protective layer 714a, formed is a second protective layer 714b that is a layer of the second insulator, and thicker than the first protective layer 714a (see FIG. 16B).

Specifically, on the barrier layer 112.ex, on which the SiAlN protective layer 714a.ex (see FIG. 16A) is formed, a SiN layer 714b.ex (one example of the second protective layer 714b) thicker than the SiAlN protective layer 714a.ex (one example of the first protective layer 714a) is deposited. The thickness of the SiN layer 714b.ex is preferably 10 nm or more and 100 nm or less (further preferably, 30 nm or more and 70 nm or less). The SiN layer 714b.ex is deposited by, for example, plasma CVD (Plasma Enhanced Chemical Vapor Deposition).

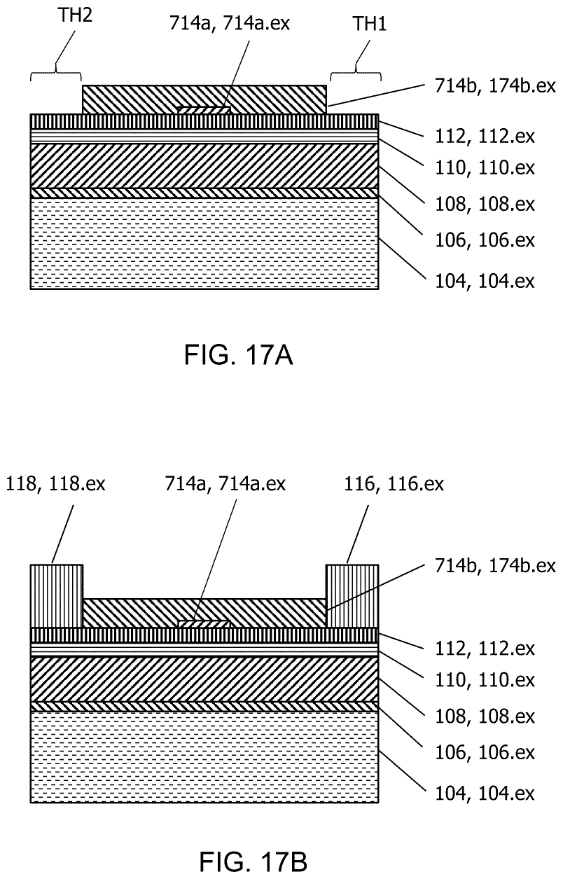

### (2-4) Formation of Drain Electrode 116 and Source Electrode 118 (see FIGS. 17A and 17B)

Then, the drain electrode 116 (see FIG. 17B) in ohmic contact with the barrier layer 112, and the source electrode 118 also in ohmic contact with the barrier layer 112 are formed.

Specifically, first, according to substantially the same procedure as that exemplified in “5-3)”, formed is an element isolation groove (not depicted) that surrounds the SiAlN layer 714a.ex, or an element isolation area of which resistance is increased by ion implantation.

Thereafter, according to substantially the same procedure as that exemplified in “5-3)”, formed are the through holes TH1, TH2 that penetrate through the SiN layer 714b.ex (see FIG. 17A). Etching is performed by dry etching. The etching gas is, for example, a fluorine type gas or a chlorine type gas.

Subsequently, according to substantially the same procedure as that exemplified in “5-3)”, a drain electrode 116.ex is formed in the through hole TH1, and a source electrode 118.ex is formed in the through hole TH2.

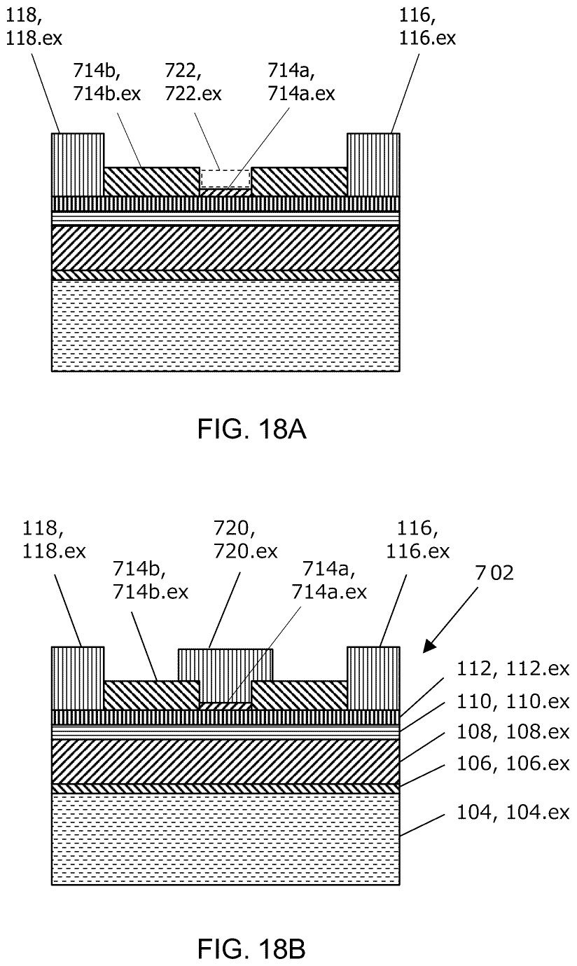

### (2-5) Formation of Through Portion 722 (see FIG. 18A)

Then, by etching a portion of the second protective layer 714b (see FIG. 17B), formed is a through portion 722 (see FIG. 18A) that penetrates through the second protective layer 714b, and exposes the first protective layer 714a.

Specifically, first, a photoresist film (not depicted) is formed on the SiN layer 714b.ex, the photoresist film having a rectangular opening directly above the SiAlN layer 714a.ex (see FIG. 17B).

Subsequently, the SiN layer 714b.ex is etched via the opening, thereby forming a through portion 722.ex (see FIG. 18A) that exposes the SiAlN layer 714a.ex. The through portion 722.ex is one example of the through portion 722. Etching is performed by, for example, dry etching. The etching gas is, for example, a fluorine type gas.

### (2-6) Formation of Gate Electrode (see FIG. 18B)

Finally, the gate electrode 720 partially arranged in the through portion 722 is formed (see FIG. 18B).

Specifically, according to substantially the same procedure as that exemplified in “(5-5)”, a gate electrode 720.ex is formed.

By the procedures up to this point, the nitride transistor 702 (one example of the nitride transistor 602) is completed.

According to Embodiment 2, a first protective layer 614a difficult to etch is present between the barrier layer 12 and the portion of the gate electrode 620 that is arranged in the through portion of the second protective layer 614b (see FIG. 13). Therefore, according to Embodiment 2, it is possible to provide a nitride transistor that achieve the high output power and the high frequency response, and has a high yield as with Embodiment 1.

Further, according to Embodiment 2, the first protective layer 614a is isolated from the drain electrode 16. For this reason, even when the insulating property of the first protective layer 614 is insufficient, it is possible to suppress the leakage current that flows between the gate electrode 620 and the drain electrode 16. The same also applies to the leakage current that flows between the gate electrode 620 and the source electrode 18.

Up to this point, Embodiments of the present invention are described. However, Embodiments 1 and 2 are illustrative, and not restrictive. For example, in each example depicted in Embodiments 1 and 2, the first protective layer is SiAlN. However, the first protective layer may be an insulator except for SiAlN. For example, the first protective layer may be Al₂O₃. Similarly, the second protective layer may be an insulator except for SiN. For example, the second protective layer may be SiO₂.

Further, in each example depicted in Embodiments 1 and 2, the substrate 4 is a SiC substrate. However, the substrate 4 may be a substrate except for SiC. For example, the substrate 4 may be silicon or sapphire.

Further, in the examples described in Embodiments 1 and 2, the through portion of the second protective layer does not reach the outer circumference of the second protective layer. However, the through portions 22 and 622 of the second protective layer may reach the outer circumference of the second protective layer. For example, the through portions 22 and 622 may be a gap that halves the second protective layer.

Further, in the examples described in Embodiments 1 and 2, the group III constituent elements possessed by the first and second nitride semiconductors are one or a plurality of In, Al, and Ga. However, the first and second nitride semiconductors may have other group III constituent elements (e.g., B) other than In, Al, and Ga.

In one aspect, in accordance with the present invention, a through portion for arranging a gate electrode is formed at a passivation film (i.e., a protective layer) without exposing a barrier layer to a plasma. For this reason, it is possible to increase the output power of a nitride transistor.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A semiconductor device, comprising:
a channel layer that is a first nitride semiconductor;
a barrier layer that is a layer of a second nitride semiconductor with a wider bandgap than that of the first nitride semiconductor, and is arranged on or above the channel layer;
a first protective layer that is a layer of a first insulator, and is arranged on or above the barrier layer;
a second protective layer that is a layer of a second insulator, is thicker than the first protective layer, and is arranged on or above the barrier layer;
a drain electrode into which a current that flows through the channel layer flows;
a source electrode that extends along the drain electrode, and from which the current flows out; and
a gate electrode that is arranged between the source electrode and the drain electrode, and is isolated from the barrier layer, wherein the first insulator is an insulator that is more difficult to remove by a certain dry etching than the second insulator,
at least a portion of the gate electrode is arranged in a through portion that penetrates through the second protective layer, and
a portion of the first protective layer is arranged under the through portion, or the first protective layer is arranged in the through portion.

2. A semiconductor device according to claim 1, wherein
the first insulator is etched more slowly than the second insulator when etched together with the second insulator by the certain dry etching.

3. A semiconductor device according to claim 1, wherein
the second protective layer is arranged above the barrier layer, with the first protective layer being sandwiched between the barrier layer and the second protective layer.

4. A semiconductor device according to claim 1, wherein
the first protective layer is in contact with the barrier layer, and the gate electrode is in contact with the first protective layer.

5. A semiconductor device according to claim 1, wherein
the first protective layer and the second protective layer are amorphous.

6. A semiconductor device according to claim 1, wherein the first protective layer is a layer of SiAlN, and the second protective layer is a layer of SiN.

7. A semiconductor device according to claim 6, wherein
a first number of atoms of Al possessed by the first protective layer is 0.17 times or more and 0.5 times or less a sum of a second number of atoms of Si possessed by the first protective layer and the first number of atoms.

8. A semiconductor device according to claim 1, wherein
the second protective layer is arranged above the barrier layer, with the first protective layer being sandwiched between the barrier layer and the second protective layer, and
the first protective layer has a dent under the through portion.

9. A method for manufacturing a semiconductor device, the method comprising:
forming a channel layer that is a first nitride semiconductor, and a barrier layer that is a layer of a second nitride semiconductor with a wider bandgap than that of the first nitride semiconductor and generates a two dimensional electron gas in the channel layer, on or above a substrate in this order;
after the forming of the channel layer and the barrier layer, forming a first protective layer that is a first insulator, and a second protective layer that is a layer of a second insulator and is thicker than the first protective layer, on or above the barrier layer in this order;
after the forming of the first protective layer and the second protective layer, forming a through portion that penetrates through the second protective layer, by etching a portion of the second protective layer; and
after the forming of the through portion, forming a gate electrode at least partially arranged in the through portion, wherein the first insulator is an insulator that is more difficult to remove by a certain dry etching than the second insulator.

10. A semiconductor device according to claim 1, wherein
the second protective layer is arranged on the barrier layer, without the first protective layer being sandwiched between the barrier layer and the second protective layer,
the first protective layer is arranged between the drain electrode and the source electrode, and is isolated from the drain electrode and the source electrode,
the first protective layer is further arranged in the through portion that penetrates through the second protective layer, and
at least a portion of the gate electrode is arranged so as to be situated on or above the first protective layer in the through portion.

11. A semiconductor device according to claim 1, further comprising a spacer layer that is a layer of a nitride semiconductor, and is arranged between the channel layer and the barrier layer, wherein
the spacer layer is a layer configured to relax an intensity of an electric field generated at the barrier layer by a potential difference between the gate electrode and the drain electrode.

12. A semiconductor device according to claim 1, wherein
the barrier layer and the channel layer are configured such that a two dimensional electron gas is generated in the channel layer, and
the first protective layer and the second protective layer are configured to suppress current collapse.

13. A semiconductor device according to claim 1, wherein
one of constituent elements of the first nitride semiconductor is Ga, and
at least two of constituent elements of the second nitride semiconductor are two elements selected from the group that consists of In, Al, and Ga.

14. A semiconductor device according to claim 13, wherein
the first nitride semiconductor is GaN, and
the second nitride semiconductor is InAlGaN.
